(19) United States
(12) Patent Application Publication
(10) Pub. No.: US 2015/0198684 A1
(43) Pub. Date: Jul. 16, 2015

(54) System and Method For Flexible Automated Magnetic Resonance Imaging Reconstruction

(71) Applicants: Tamer Basha, Revere, MA (US); Reza Nezafat, Newton, MA (US)

(72) Inventors: Tamer Basha, Revere, MA (US); Reza Nezafat, Newton, MA (US)

(21) Appl. No.: 14/595,544

(22) Filed: Jan. 13, 2015

Related U.S. Application Data
(60) Provisional application No. 61/926,716, filed on Jan. 13, 2014.

(51) Int. Cl. G01R 33/48

(52) U.S. Cl. CPC G01R 33/4818

(57) ABSTRACT

A system and method for initiating a specific reconstruction or processing method is provided. After an MRI scan is completed, an operator of the MRI scanner can choose the processing to occur on the scanner machine or on a different remote station on the network or even on a central processing unit (CPU) cluster or graphics processing unit (GPU) server on the same network. During the processing, the server can connect with the remote processing workstation and update the progress of the operation. After finishing, the results may be automatically or manually retrieved from the remote processing unit and directly sent to the scanner database, where the results can be viewed and stored similar to images reconstructed by a vendor reconstruction system.

### CROSS-REFERENCE TO RELATED APPLICATIONS

This application is based on, claims the benefit of, and incorporates herein by reference, U.S. Provisional Patent Application No. 61/926,716 filed on Jan. 13, 2014, and entitled “SOFTWARE PLATFORM FOR FLEXIBLE AUTOMATED MAGNETIC RESONANCE IMAGING RECONSTRUCTION.”

### STATEMENT REGARDING FEDERALLY SPONSORED RESEARCH

This invention was made with government support under NIH: R01EB008743-01A2 awarded by National Institutes of Health. The government has certain rights in the invention.

### BACKGROUND OF THE INVENTION

The field of the invention is magnetic resonance imaging (MRI) methods and systems. More particularly, the invention relates to a system and method for flexible automated MRI reconstruction.

When a substance such as human tissue is subjected to a uniform magnetic field (polarizing field B₀), the individual magnetic moments of the excited nuclei in the tissue attempt to align with this polarizing field, but precess about it in random order at their characteristic Larmor frequency. If the substance, or tissue, is subjected to a magnetic field (excitation field B₁) which is in the x-y plane and which is near the Larmor frequency, the net aligned moment, M_{z}, may be rotated, or “tipped”, into the x-y plane to produce a net transverse magnetic moment Mₜ. A signal is emitted by the excited nuclei or “spins”, after the excitation signal B₁ is terminated, and this signal may be received and processed to form an image.

When utilizing these “MR” signals to produce images, magnetic field gradients (Gₓ, G_{y}, and G_{z}) are employed. Typically, the region to be imaged is scanned by a sequence of measurement cycles in which these gradients vary according to the particular localization method being used. The resulting set of received MR signals are digitized and processed to reconstruct the image using one of many well known reconstruction techniques.

The measurement cycle used to acquire each MR signal is performed under the direction of a pulse sequence produced by a pulse sequencer. Clinically available MRI systems store a library of such pulse sequences that can be prescribed to meet the needs of many different clinical applications. Research MRI systems include a library of clinically proven pulse sequences and they also enable the development of new pulse sequences.

The MR signals acquired with an MRI system are signal samples of the subject of the examination in Fourier space, or what is often referred to in the art as “k-space”. Each MR measurement cycle, or pulse sequence, typically samples a portion of k-space along a sampling trajectory characteristic of that pulse sequence. Most pulse sequences sample k-space in a roster scan-like pattern sometimes referred to as a “spin-warp”, a “Fourier”, a “rectilinear”, or a “Cartesian” scan. The spin-warp scan technique is discussed in an article entitled “Spin-Warp MR Imaging and Applications to Human Whole-Body Imaging” by W. A. Edelstein et al., Physics in Medicine and Biology, Vol. 25, pp. 751-756 (1980). It employs a variable amplitude phase encoding magnetic field gradient pulse prior to the acquisition of MR spin-echo signals to phase encode spatial information in the direction of this gradient. In a two-dimensional implementation (2DFT), for example, spatial information is encoded in one direction by applying a phase encoding gradient (G_{y}) along that direction, and then a spin-echo signal is acquired in the presence of a readout magnetic field gradient (Gₓ) in a direction orthogonal to the phase encoding direction. The readout gradient present during the spin-echo acquisition encodes spatial information in the orthogonal direction. In a typical 2DFT pulse sequence, the magnitude of the phase encoding gradient pulse G_{y} is incremented (ΔG_{y}) in the sequence of measurement cycles, or “views” that are acquired during the scan to produce a set of k-space MR data from which an entire image can be reconstructed.

An image is reconstructed from the acquired k-space data by transforming the k-space data set to an image space data set. There are many different methods for performing this task and the method used is often determined by the technique used to acquire the k-space data. With a Cartesian grid of k-space data that results from a 2D or 3D spin-warp acquisition, for example, the most common reconstruction method used is an inverse Fourier transformation (“2DFT” or “3DFT”) along each of the 2 or 3 axes of the data set. With a radial k-space data set and its variations, the most common reconstruction method includes “regridding” the k-space samples to create a Cartesian grid of k-space samples and then perform a 2DFT or 3DFT on the regridded k-space data set. In the alternative, a radial k-space data set can also be transformed to Radon space by performing a 1DFT of each radial projection view and then transforming the Radon space data set to image space by performing a filtered backprojection.

MRI systems are available from a variety of manufactures. However, each manufacturer uses proprietary systems and, thus, integration of new and improved image reconstruction and processing methods into clinical workflow has been hampered by integration with vendors' proprietary systems and software. While all vendors allow modification of imaging sequences, implementation of or adjustments to reconstruction techniques are not available to clinicians. To allow clinicians and researchers the flexibility to implement or use alternative reconstruction processes, some have moved raw image data, k-space data, to networked computer systems configured to implement the new or alternative reconstruction processes. For example, one workflow includes manually exporting the data, performing the custom reconstruction using stand-alone programming language (e.g., Matlab, C++, and the like) implementation, and then visualizing the results on a different workstation. This process usually requires an expert user and is not feasible in common clinical workflow.

Therefore, it would be desirable to have systems and methods for providing improved or new systems and methods for enabling users to rapidly integrate post-processing and reconstruction methods developed in any programming language on any type of workstation via a network connection, directly visualize the data on the scanner console, and store the data.

### SUMMARY OF THE INVENTION

The present invention overcomes the aforementioned drawbacks by providing a system and method for initiating a specific reconstruction or processing method. After an MRI scan is completed, the operator of the MRI scanner can choose the processing to occur on the scanner machine or on a different remote station on the network or even on a central processing unit (CPU) cluster or graphics processing unit (GPU) server on the same network. During the processing, the server can connect with the remote processing workstation and update the progress of the operation. After finishing, the results may be automatically or manually retrieved from the remote processing unit and directly sent to the scanner database, where the results can be viewed and stored similar to images reconstructed by a vendor reconstruction system.

In accordance with one aspect of the inventions, a method for reconstructing images of at least one subject with a reconstruction tool integrated with a magnetic resonance imaging (MRI) system is disclosed. The method includes acquiring, with the MRI system, raw image data from the at least one subject using a pulse sequence server. Using the reconstruction tool, a list of patient scans corresponding to the raw image data for the at least one subject is generated. An input selection of at least one patient scan from the list of patient scans is received from the user interface of the reconstruction tool. Then an image reconstruction selection from a plurality of image reconstruction methods is received from the user interface of the reconstruction tool. The plurality of image reconstruction methods are capable of being applied to the raw image data regardless of a manufacturer of the MRI system. Reconstructed images are produced of the raw image data of the at least one patient scan using the image reconstruction selection.

In accordance with one aspect of the invention, a system for reconstructing images of at least one subject with a magnetic resonance imaging (MRI) system is disclosed. The system includes a pulse sequence server in communication with the MRI system. The pulse sequence server is configured to acquire raw image data from the at least one subject. The system further includes a reconstruction tool integrated into the MRI system for generating a list of patient scans corresponding to the raw image data for the at least one subject. A user interface of the reconstruction tool is provided for receiving an input selection of at least one patient scan from the list of patient scans. An image reconstruction selection is received from the user interface from a plurality of image reconstruction methods, and the plurality of image reconstruction methods are capable of being applied to the raw image data regardless of a manufacturer of the MRI system to produce reconstructed images of the raw image data of the at least one patient scan using the image reconstruction selection.

The foregoing and other aspects and advantages of the invention will appear from the following description. In the description, reference is made to the accompanying drawings that form a part hereof, and in which there is shown by way of illustration a preferred embodiment of the invention. Such embodiment does not necessarily represent the full scope of the invention, however, and reference is made therefore to the claims and herein for interpreting the scope of the invention.

### BRIEF DESCRIPTION OF THE DRAWINGS

FIG. 1 is a block diagram of an MRI system configured for use with the present invention.

FIG. 2 is a block diagram of a layout of a floor of a clinical facility where the present invention may be used.

FIG. 3 is a schematic diagram of connections between a program in accordance with the present invention, an MRI scanner, and remote processing units.

FIG. 4 is a flowchart setting forth the steps of an example of a method for image reconstruction in accordance with the present invention.

FIG. 5 is a screen shot showing an example user interface provided by the program including a list of patients.

FIG. 6 is a screen shot showing the user interface of FIG. 5 and including a list of patient scans for a selected patient.

FIG. 7 is a screen shot showing the user interface of FIG. 6 after patient scans have been selected by a user and sent for image reconstruction.

FIG. 8 is a screen shot showing the user interface displaying the reconstructed images at the scanner console.

### DETAILED DESCRIPTION OF THE INVENTION

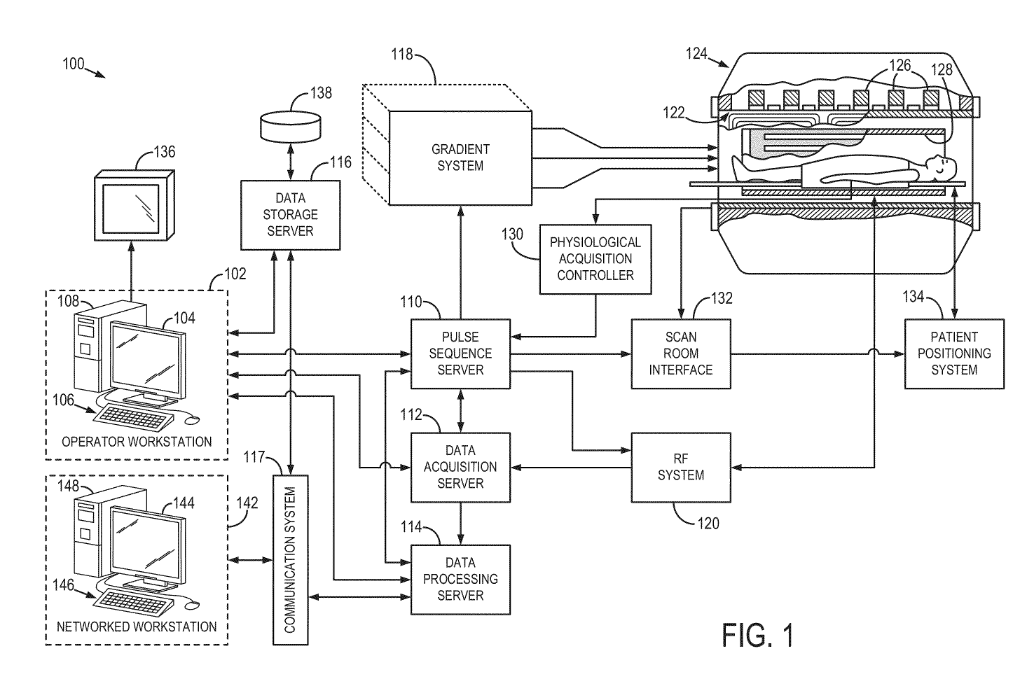

Referring particularly now to FIG. 1, an example of a magnetic resonance imaging (MRI) system 100 is illustrated. The MRI system 100 includes an operator workstation 102, which will typically include a display 104, one or more input devices 106, such as a keyboard and mouse, and a processor 108. The processor 108 may include a commercially available programmable machine running a commercially available operating system. The operator workstation 102 provides the operator interface that enables scan prescriptions to be entered into the MRI system 100. In general, the operator workstation 102 may be coupled to four servers: a pulse sequence server 110; a data acquisition server 112; a data processing server 114; and a data storage server 116.

The operator workstation 102 and each server 110, 112, 114, and 116 are connected to communicate with each other. For example, the servers 110, 112, 114, and 116 may be connected via a communication system 117, which may include any suitable network connection known in the art or developed in the future including, but not limited to wired, wireless, modem, dial-up, satellite, cable modem, Digital Subscriber Line (DSL), Asymmetric Digital Subscribers Line (ASDL), Virtual Private Network (VPN), Integrated Services Digital Network (ISDN), X.25, Ethernet, token ring, Fiber Distributed Data Interface (FDDI), IP over Asynchronous Transfer Mode (ATM), Infrared Data Association (IrDA), wireless, WAN technologies (T1, Frame Relay), Point-to-Point Protocol over Ethernet (PPPoE), and/or any combination thereof. As an example, the communication system 117 may include both proprietary or dedicated networks, as well as open networks, such as the internet.

The pulse sequence server 110 functions in response to instructions downloaded from the operator workstation 102 to operate a gradient system 118 and a radiofrequency (“RF”) system 120. Gradient waveforms necessary to perform the prescribed scan are produced and applied to the gradient system 118, which excites gradient coils in an assembly 122 to produce the magnetic field gradients Gₓ, G_{y}, and G_{z} used for position encoding magnetic resonance signals. The gradient coil assembly 122 forms part of a magnet assembly 124 that includes a polarizing magnet 126 and a whole-body RF coil 128.

RF waveforms are applied by the RF system 120 to the RF coil 128, or a separate local coil (not shown in FIG. 1), to perform the prescribed magnetic resonance pulse sequence. Responsive magnetic resonance signals detected by the RF coil 128, or a separate local coil (not shown in FIG. 1), are received by the RF system 120, where they are amplified, demodulated, filtered, and digitized under direction of commands produced by the pulse sequence server 110. The RF system 120 includes an RF transmitter for producing a wide variety of RF pulses used in MRI pulse sequences. The RF transmitter is responsive to the scan prescription and direction from the pulse sequence server 110 to produce RF pulses of the desired frequency, phase, and pulse amplitude waveform. The generated RF pulses may be applied to the whole-body RF coil 128 or to one or more local coils or coil arrays (not shown in FIG. 1).

The RF system 120 also includes one or more RF receiver channels. Each RF receiver channel includes an RF preamplifier that amplifies the magnetic resonance signal received by the coil 128 to which it is connected, and a detector that detects and digitizes the I and Q quadrature components of the received magnetic resonance signal. The magnitude of the received magnetic resonance signal may, therefore, be determined at any sampled point by the square root of the sum of the squares of the I and Q components:

M=\sqrt{I²+Q₂} Eqn. 1;

and the phase of the received magnetic resonance signal may also be determined according to the following relationship:

$$ϕ = {tan}^{- 1} ( \frac{Q}{I} ) . \qquad Eqn . 2$$

The pulse sequence server 110 also optionally receives patient data from a physiological acquisition controller 130. By way of example, the physiological acquisition controller 130 may receive signals from a number of different sensors connected to the patient, such as electrocardiograph (“ECG”) signals from electrodes, or respiratory signals from a respiratory bellows or other respiratory monitoring device. Such signals are typically used by the pulse sequence server 110 to synchronize, or “gate,” the performance of the scan with the subject's heart beat or respiration.

The pulse sequence server 110 also connects to a scan room interface circuit 132 that receives signals from various sensors associated with the condition of the patient and the magnet system. It is also through the scan room interface circuit 132 that a patient positioning system 134 receives commands to move the patient to desired positions during the scan.

The digitized magnetic resonance signal samples produced by the RF system 120 are received by the data acquisition server 112. The data acquisition server 112 operates in response to instructions downloaded from the operator workstation 102 to receive the real-time magnetic resonance data and provide buffer storage, such that no data is lost by data overrun. In some scans, the data acquisition server 112 does little more than passing the acquired magnetic resonance data to the data processor server 114. However, in scans that require information derived from acquired magnetic resonance data to control the further performance of the scan, the data acquisition server 112 is programmed to produce such information and convey it to the pulse sequence server 110. For example, during prescans, magnetic resonance data is acquired and used to calibrate the pulse sequence performed by the pulse sequence server 110. As another example, navigator signals may be acquired and used to adjust the operating parameters of the RF system 120 or the gradient system 118, or to control the view order in which k-space is sampled. In still another example, the data acquisition server 112 may also be employed to process magnetic resonance signals used to detect the arrival of a contrast agent in a magnetic resonance angiography (MRA) scan. By way of example, the data acquisition server 112 acquires magnetic resonance data and processes it in real-time to produce information that is used to control the scan.

The data processing server 114 receives magnetic resonance data from the data acquisition server 112 and processes it in accordance with instructions downloaded from the operator workstation 102. Such processing may, for example, include one or more of the following: reconstructing two-dimensional or three-dimensional images by performing a Fourier transformation of raw k-space data; performing other image reconstruction algorithms, such as iterative or backprojection reconstruction algorithms; applying filters to raw k-space data or to reconstructed images; generating functional magnetic resonance images; calculating motion or flow images; and so on.

Images reconstructed by the data processing server 114 are conveyed back to the operator workstation 102 where they are stored. Real-time images are stored in a data base memory cache (not shown in FIG. 1), from which they may be output to operator display 104 or a display 136 that is located near the magnet assembly 124 for use by attending physicians. Batch mode images or selected real time images are stored in a host database on disc storage 138. When such images have been reconstructed and transferred to storage, the data processing server 114 notifies the data storage server 116 on the operator workstation 102. The operator workstation 102 may be used by an operator to archive the images, produce films, or send the images via a network to other facilities.

The MRI system 100 may also include one or more networked workstations 142. By way of example, a networked workstation 142 may include a display 144; one or more input devices 146, such as a keyboard and mouse; and a processor 148. The networked workstation 142 may be located within the same facility as the operator workstation 102, or in a different facility, such as a different healthcare institution or clinic.

The networked workstation 142, whether within the same facility or in a different facility as the operator workstation 102, may gain remote access to the data processing server 114 or data storage server 116 via the communication system 117. Accordingly, multiple networked workstations 142 may have access to the data processing server 114 and the data storage server 116. In this manner, magnetic resonance data, reconstructed images, or other data may exchange between the data processing server 114 or the data storage server 116 and the networked workstations 142, such that the data or images may be remotely processed by the networked workstation 142. This data may be exchanged in any suitable format, such as in accordance with the transmission control protocol (TCP), the internet protocol (IP), or other known or suitable protocols.

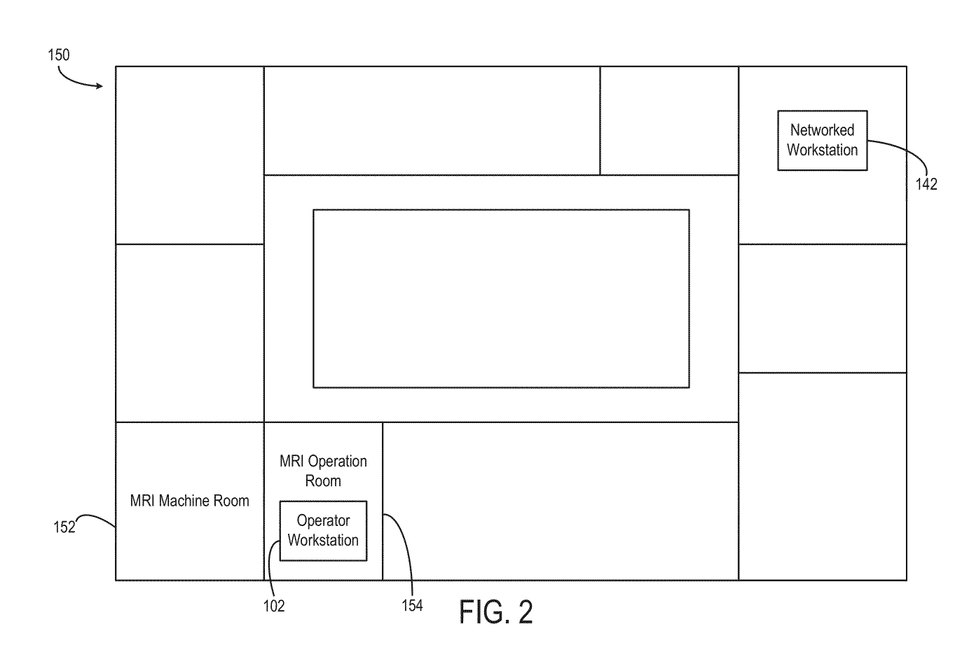

Referring now to FIG. 2, an example of a layout of a floor of a clinical facility 150 where the present invention may be used is illustrated. The clinical facility 150 includes an MRI machine room 152, an MRI operation room 154 with the operator workstation 102, and a room with the networked workstation 142. The operator workstation 102 and the networked workstation 142 are in communication such that data may be sent from the operator workstation 102 to the networked workstation 142 for reconstruction. The networked workstation 142 is shown on the same floor as the operator workstation 102, however the networked workstation 142 maybe be within the same facility on a different floor or in a different facility than the operator workstation 102. As will be explained, the present disclosure provides a system and method where a user present at the operator workstation 102 may utilize the networked workstation 142 to perform or assist with a reconstruction process without requiring the user to travel to the networked workstation 142 or program coordinated operation of the operator workstation 102 and networked workstation 142.

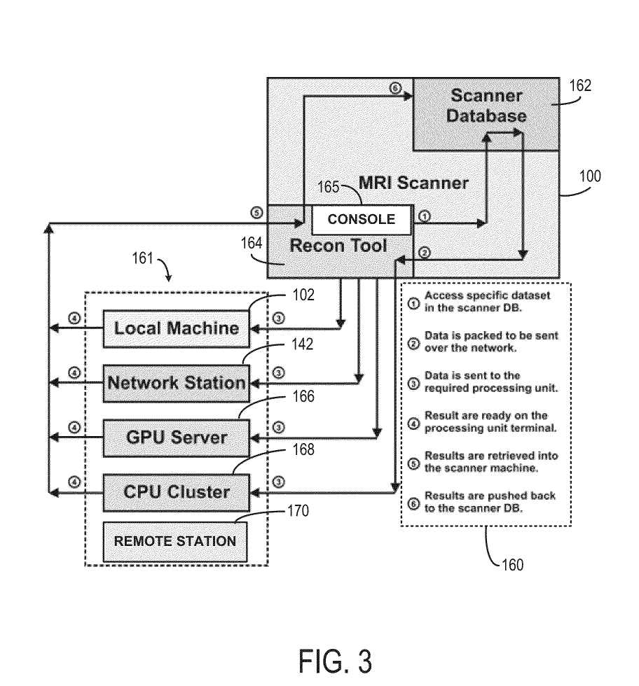

Referring now to FIG. 3, a schematic diagram of the connections between a program 160, MRI system 100, and processing units 161 (such as may be located at the networked workstation 142 or any other local or remote system) is illustrated. The MRI system 100 has a scanner database 162 (such as the data storage server 116 of FIG. 1) and a reconstruction tool 164 (such as may function within a system such as the data processing server 114 of FIG. 1). The reconstruction tool 164 may be communicatively connected to a scanner console 165 to allow a user to navigate various features of the program 160. After an MRI scan is completed, the operator can invoke the program 160 on the scanner console 165 to initiate a specific reconstruction or processing method. The operator can choose the processing to occur on the local/operator workstation 102, on the networked workstation 142 or a remote workstation 170. Additionally, or alternatively the operator may choose the processing to occur on a CPU cluster 166 or a GPU server 168. During the processing, the program 160 can operate within the MRI system 100 on any of the above described processing units 161 and facilitate connection and communication therebetween to implement a desired reconstruction process. Once the reconstruction is finished, the results may be automatically or manually returned or delivered to the scanner database 162 or other location, where the results can be viewed on the scanner console 165 and stored similar to images reconstructed by a vendor reconstruction system.

As illustrated, within this general example of an architecture, the program 160 is designed to facilitate a plurality of operations. For example, the program 160 can readily access specific datasets stored in the scanner database 162. This can be achieved by leveraging the reconstruction tools 164 to communicate with the scanner database 162. In particular, the information can be sent as data that is packed to be sent over the network. Accordingly, the data can be sent to one or more of the plurality of processing units 161 described above for processing/reconstruction and the results may be returned back to the scanner console 165 of the MRI system 100. Once returned to the MRI system 100, the data may then be pushed back, for example, by the reconstruction tool 164, to the scanner database 162. Accordingly, to the clinician, the program 160 facilitates processing/reconstruction by moving raw data from the scanner database 162 and returning processed images to the scanner database 162. As such, the user or clinician need not coordinate operation of or operate any remote processing systems directly.

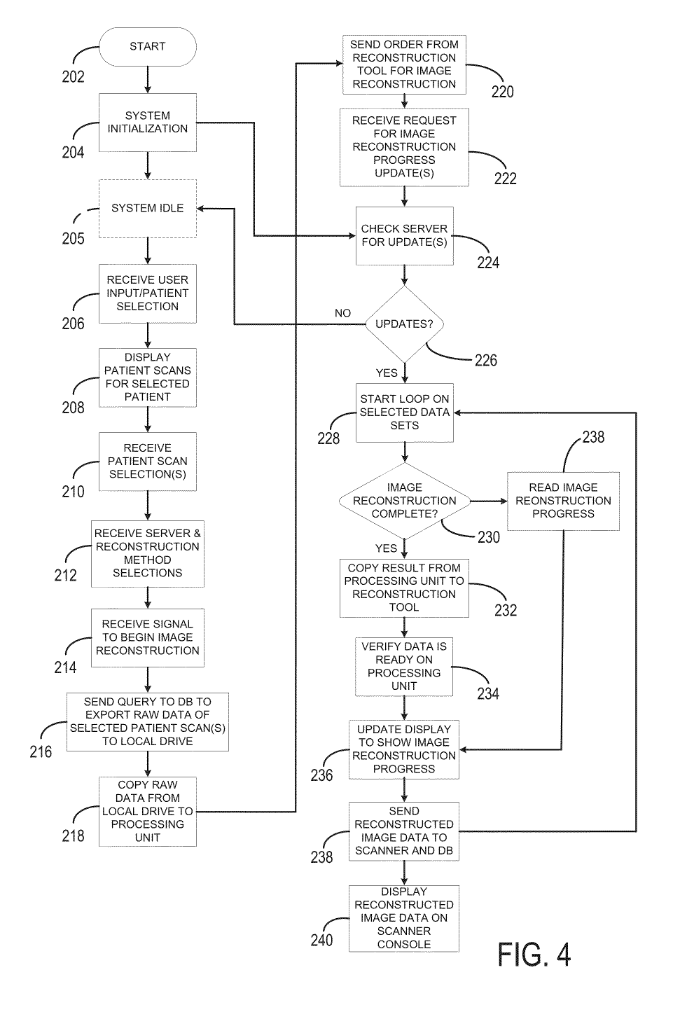

Referring now to FIG. 4, a flowchart setting forth the steps of an example method for integrating post-processing and reconstruction of image data is illustrated. The user, such as a clinician, begins by starting the program 160 at the scanner console 165, as indicated in step 202. After the program 160 is started in step 202, an initialization process begins, as indicated in step 204. The initialization process of step 204 may include, for example, checking connections to the listed servers and the processing units 161, enumerating the patients in the scanner database 162, and starting a timer configured to check for server updates. Once the initialization process is complete, the program 160 may optionally enter an idle stage at step 205 if there is no user interaction with the program 160. During the idle stage, the program 160 can be closed if desired.

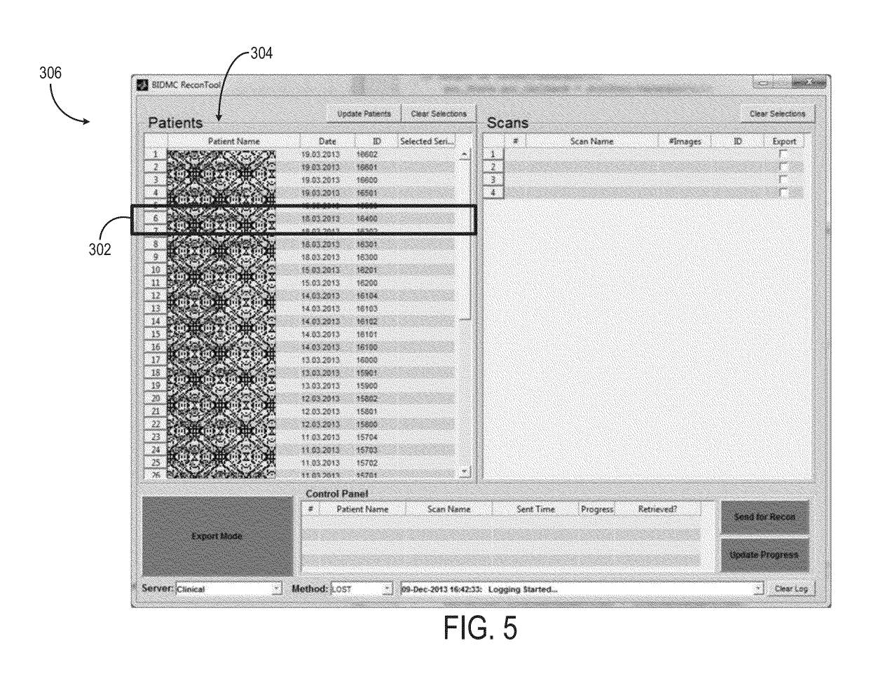

However, if the program 160 detects user interaction, the system idle step 205 may be bypassed and the program 160 can receive a user input at step 206. The input received at step 206 may include the clinician, for example, selecting a patient from a list of patients. In one non-limiting example, as shown in FIG. 5, a patient 302 can be selected from a list of patients 304 on a user interface 306 provided on the scanner console 165 of the reconstruction tool 164 of FIG. 3, for example. The user interface 306 may be provided to the user by the program 160 hosted by one or more of the processing units 161 of FIG. 3.

The user interface 306 displayed on the scanner console 165 may be any graphical, textual, scanned and/or auditory information a computer program presents to the user, and the control sequences such as keystrokes, movements of the computer mouse, selections with a touch screen, scanned information etc. used to control the program. Examples of such interfaces include any known or later developed combination of Graphical User Interfaces (GUI) or Web-based user interfaces as seen in and after FIG. 5, including Touch interfaces, Conversational Interface Agents, Live User Interfaces (LUI), Command line interfaces, Non-command user interfaces, Object-oriented User Interfaces (OOUI) or Voice user interfaces. Any information generated by the user, or any other information, may be accepted using any field, widget and/or control used in such interfaces, including but not limited to a text-box, text field, button, hyper-link, list, drop-down list, check-box, radio button, data grid, icon, graphical image, embedded link, etc.

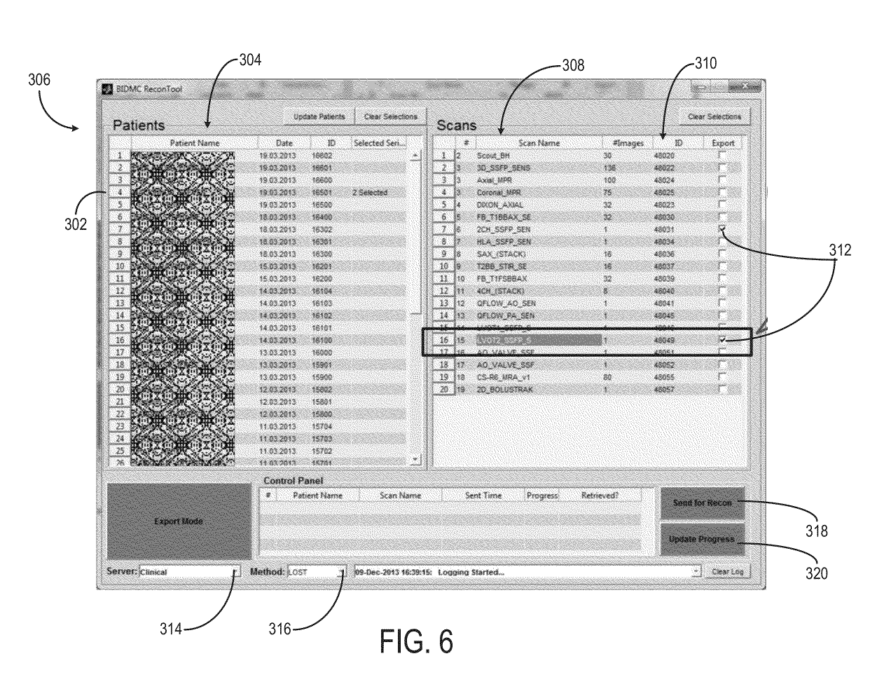

Once the user selects the patient 302 from the list of patients 304 at step 206, the program 160 displays the patient scans for the selected patient using, for example, a scan ID, as indicated in step 208. At step 210, the program 160 may receive selections of one or more patient scans of the selected patient from the user. For example, as shown in FIG. 6, once the patient 302 is selected on the user interface 306, corresponding patient scans 308 and scan IDs 310 for the selected patient may be displayed on the user interface 306. Checkboxes 312 may be provided on the user interface 306 to allow the user to select one or more of the patient scans 308 for processing.

Returning to FIG. 4, once the program 160 has received the patient scan selections, server selections and image reconstruction methods may be received by the program 160 at step 212. The server selection may identify which of the processing units 161 of FIG. 3, for example, the patient scans are to be processed on. The image reconstruction method may include, for example, a low-dimensional-structure self-learning and threshold (LOST) method which learns the image areas of similar signal characteristics and uses this information for reconstruction. Generally, a low resolution image from a substantially fully-sampled portion of the image data, such as the central portion of k-space, is reconstructed, from which image blocks containing similar image characteristics, such as anatomical characteristics, are identified. These image blocks may be arranged into “similarity clusters,” which are subsequently processed for de-aliasing and artifact removal using underlying low-dimensional properties. Alternatively, other methods can be implemented to reconstruct an estimate image, from which similarity clusters are identified. For example, a total variation (TV) method or a nonlinear conjugate gradient method may be used as the image reconstruction method. As shown in FIG. 6, the server selection specified by the user can be selected using a pull-down menu, such as the pull-down menu 314 shown on the user interface 306. Similarly, the method of image reconstruction specified by the user can be selected using pull-down menu 316, for example, shown on the user interface 306.

Once the program receives the server and image reconstruction method at step 212 shown in FIG. 4, the program 160 may receive a signal to begin image reconstruction at step 214. The signal to begin image reconstruction may be generated, for example, when the user selects a “send for reconstruction” button 318 on the user interface 306 of FIG. 6. Using the scan ID 310, a query may be sent to the scanner database 162 to export the raw data of the patient scan(s) 308 to the local drive of the reconstruction tool 164, as indicated in step 216. Next, the raw data from the local drive of the reconstruction tool 164 may be copied to the chosen processing unit 161 or active server, as indicated in step 218. After the raw data is copied, an order may be sent from the reconstruction tool 164 to start the image reconstruction process on the processing unit 161 or active server, as indicated in step 220.

Upon receiving the “Starting order”, the processing unit 161 loops on the existing datasets. For each dataset, an associated setting file may determine if the dataset is currently under processing or not. Whenever one dataset is neither under processing nor has been processed before, the processing unit 161 may execute a new instance from the reconstruction algorithms executable available on the processing unit 161. The reconstruction executable may be chosen based on the required processing algorithm sent from the reconstruction tool 164. When the algorithm executable runs, it first checks that the necessary expected data files exist, and that the data files are in a known format, since raw data format varies based on the vendor of the MRI system. If, however, the data file is not in a known format, the reconstruction process ends, and a “failure to reconstruct” signal may be indicated in the setting file.

If one or more image reconstruction processes are in progress, the program 160 may receive a request from the clinician for an update on the progress of image reconstructions, as indicated in step 222. In one non-limiting example, the request to update the progress of the image reconstruction may be generated, for example, when the user selects an “Update progress” button 320 on the user interface 306 of FIG. 6. Once the request for updated progress is received at step 222, the program 160 checks the reconstruction tool 164 server for updates, as indicated in step 224. The program 160 may also check for updates of image reconstructions using the timer initialized in step 204. For example, the timer may be programmed to check the processing unit 161 server for image reconstruction updates every minute.

On the processing unit 161, whenever the reconstruction processes have updates, an update flag may be raised and read by the reconstruction tool 164. If there are no updates to the image reconstructions at decision step 226, the program 160 may go to the idle stage at step 205. If, however, image reconstruction updates are detected at decision step 226, the program 160 starts a loop on all selected data sets on the processing unit 161 server, as indicated in step 228. Each dataset on the processing unit 161 may have an associated setting file that reports the current progress of the reconstruction process. Upon receiving the update flag, the program 160 may start looping over the datasets, read the progress of each dataset reconstruction, and update the progress to the program screen.

Next, at decision step 230, the program 160 determines whether the image reconstruction process is complete. If image reconstruction is complete at decision step 230, the program 160 may copy the result indicating the image reconstruction is complete from the processing unit 161 server to the local drive of the reconstruction tool 164 as indicated in step 232. Next, the program 160 verifies the data is ready on the local drive of the processing unit 161 by checking that the expected files exist and are not shared by any other processes (i.e., the copying process is completely done), as indicated in step 234, and updates the display of the scanner console 165 with the progress of the image reconstructions, as indicated in step 236.

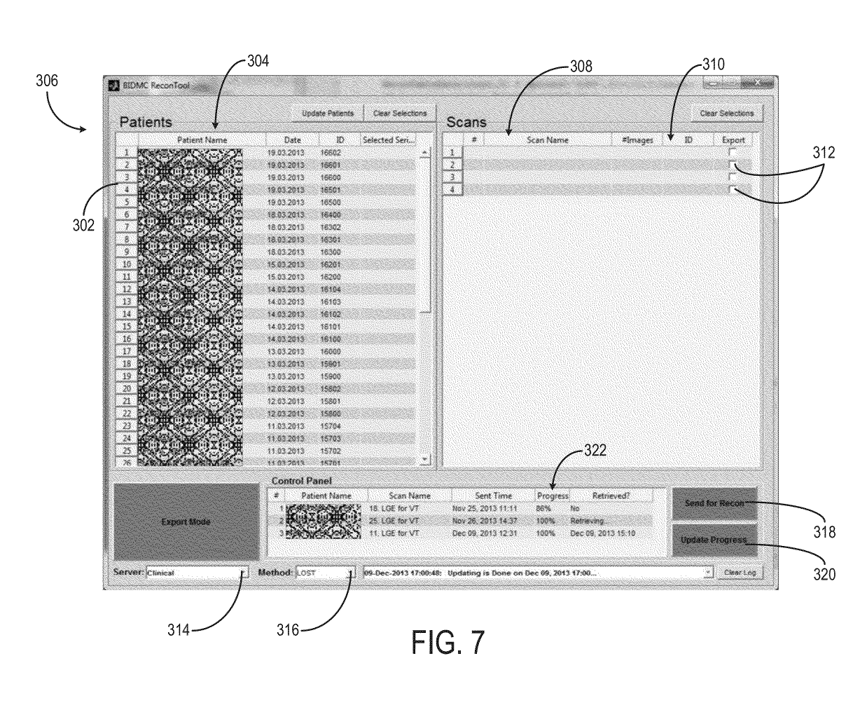

If, however, the image reconstruction is not complete at decision step 230, the program 160 may be configured to read the image reconstruction progress, as indicated in step 238, and update the scanner console 165 display with the progress of the image reconstructions, as indicated in step 236. In one non-limiting example, as shown in FIG. 7, a progress indicator 322 of the image reconstruction progress may be displayed to the user on the user interface 306 of the scanner console 165. In the example user interface 306 shown, the progress indicator 322 is represented by a numerical percentage. In an alternative example, the progress indicator 322 may be shown as a fractional value that indicates the quantity of images completed over the total quantity of images in the specific patient scan 308.

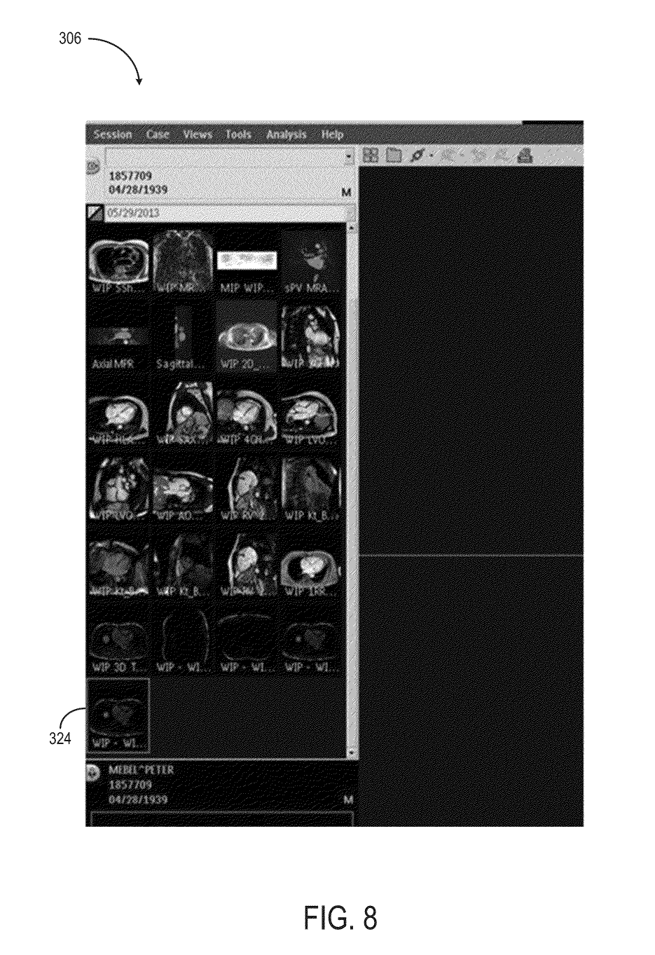

Returning to FIG. 4, once the image construction is complete for the patient scan 308, the reconstructed image data is sent to the MRI scanner 100 and the scanner database 162 at step 238. The above described process continues on to the next data set until the loop started in step 228 is complete. The reconstructed images are then available on the image database for displaying on the scanner console 165 of the MRI system 100, as indicated at step 240. As a non-limiting example, as shown in FIG. 8 the user interface 306 shows reconstructed images 324 of the selected patient at the scanner console 165.

The present invention has been described in terms of one or more preferred embodiments, and it should be appreciated that many equivalents, alternatives, variations, and modifications, aside from those expressly stated, are possible and within the scope of the invention.

1. A method for reconstructing images of at least one subject with a reconstruction tool integrated into a magnetic resonance imaging (MRI) system, the steps comprising:
a) acquiring, with the MRI system, raw image data from the at least one subject using a pulse sequence server;
b) generating, with the reconstruction tool, a list of patient scans corresponding to the raw image data for the at least one subject;
c) receiving, from a user interface of the reconstruction tool, an input selection of at least one patient scan from the list of patient scans;
d) receiving, from the user interface of the reconstruction tool, an image reconstruction selection from a plurality of image reconstruction methods, the plurality of image reconstruction methods capable of being applied to the raw image data regardless of a manufacturer of the MRI system; and
e) producing reconstructed images of the raw image data of the at least one patient scan using the image reconstruction selection.

2. The method of claim 1 wherein step d) includes receiving, from the user interface of the reconstruction tool, another input selection of at least one processing unit to which the raw image data is exported and the selected image reconstruction method is applied.

3. The method of claim 2 wherein the at least one processing unit is communicatively coupled to the reconstruction tool, the at least one processing unit includes at least one of a local machine, a network station, a GPU server, a CPU cluster, and a remote station.

4. The method of claim 2 wherein step e) includes at least one of manually and automatically delivering the reconstructed images from the at least one processing unit back to a scanner database incorporated into the MRI system.

5. The method of claim 4 further comprising the steps of:
accessing the reconstructed images from the scanner database; and
displaying the reconstructed images on a scanner console incorporated into the MRI system.

6. The method of claim 4 further comprising the step of initializing the reconstruction tool to at least one of checking a connection to the at least one processing unit, enumerating the list of patient scans in the scanner database, and starting a timer configured to check for updates related to the at least one processing unit.

7. The method of claim 1 wherein the plurality of reconstruction methods includes at least one of a LOST method, a total variation (TV) method, and a nonlinear conjugate gradient method.

8. The method of claim 1 further comprising the step of receiving, from the user interface, a request for an update related to a transformation of the raw image data into the reconstructed images.

9. The method of claim 8 further comprising providing, on the user interface, a progress indicator in response to the request for the update, the progress indicator representative of a state of completion of the image reconstruction progress.

10. The method of claim 8 wherein the reconstruction tool includes a timer configured to request the update related to the transformation of the raw image data into the reconstructed images at a predetermined time interval.

11. A system for reconstructing images of at least one subject with a magnetic resonance imaging (MRI) system, the system comprising:
a pulse sequence server in communication with the MRI system, the pulse sequence server configured to acquire raw image data from the at least one subject;
a reconstruction tool integrated into the MRI system for generating a list of patient scans corresponding to the raw image data for the at least one subject;
a user interface of the reconstruction tool for receiving an input selection of at least one patient scan from the list of patient scans; and
wherein an image reconstruction selection is received from the user interface from a plurality of image reconstruction methods, the plurality of image reconstruction methods capable of being applied to the raw image data regardless of a manufacturer of the MRI system to produce reconstructed images of the raw image data of the at least one patient scan using the image reconstruction selection.

12. The system of claim 11 wherein the user interface of the reconstruction tool is configured to receive another input selection of at least one processing unit to which the raw image data is exported and the selected image reconstruction method is applied.

13. The system of claim 12 wherein the at least one processing unit is communicatively coupled to the reconstruction tool, the at least one processing unit includes at least one of a local machine, a network station, a GPU server, a CPU cluster, and a remote station.

14. The system of claim 12 wherein the at least one processing unit is configured to at least one of manually and automatically deliver the reconstructed images back to a scanner database incorporated into the MRI system.

15. The system of claim 14 further comprising a scanner console incorporated into the MRI system for displaying the reconstructed images accessed from the scanner database.

16. The system of claim 14 further comprising an initialization tool configured to initialize the reconstruction tool to at least one of check for a connection to the at least one processing unit, enumerate the list of patient scans in the scanner database, and start a timer configured to check for updates related to the at least one processing unit.

17. The system of claim 11 wherein the plurality of reconstruction methods includes at least one of a LOST method, a total variation (TV) method, and a nonlinear conjugate gradient method.

18. The system of claim 11 further comprising a button on the user interface, wherein, upon selecting the button, a request for an update related to a transformation of the raw image data into the reconstructed images is generated.

19. The system of claim 18 further comprising a progress indicator configured to be displayed on the user interface in response to the request for the update, the progress indicator representative of a state of completion of the image reconstruction progress.

20. The system of claim 18 wherein the reconstruction tool includes a timer configured to request the update related to the transformation of the raw image data into the reconstructed images at a predetermined time interval.
